(19) United States
(12) Patent Application Publication
(10) Pub. No.: US 2025/0191956 A1
(43) Pub. Date: Jun. 12, 2025

(54) ELECTROSTATIC CHUCK DEVICE AND COOLING PLATE

(71) Applicant: HORIBA STEC, Co., Ltd., Kyoto-shi (JP)

(72) Inventors: Esteban GONZALEZ, Reno, NV (US); Ajayaketan NAYAK, Kyoto-shi (JP); Tadahiro YASUDA, Kyoto-shi (JP)

(21) Appl. No.: 18/956,305

(22) Filed: Nov. 22, 2024

(30) Foreign Application Priority Data
Dec. 11, 2023 (JP) 2023-208450

(51) Int. Cl. H01L 21/683; H01J 37/32

(52) U.S. Cl. CPC H01L 21/6833; H01J 37/32724; H01J 2237/002; H01J 2237/2007

(57) ABSTRACT

The present invention is an electrostatic chuck device which makes a temperature of a target object clamped to a clamping plate uniform and clamps the target object via an electrostatic force, including: a clamping plate having a clamping surface that clamps a target object to its front surface side; and a cooling plate which is provided on a back surface side of the clamping plate and which has an internal flow channel through which a coolant flows, in which the internal flow channel forms a flow channel geometry in which flow channel elements of an identical pattern in a plan view are systematically connected.

### CROSS-REFERENCE TO RELATED APPLICATION

The present application claims priority to Japanese Patent Application No. 2023-208450 filed Dec. 11, 2023, entitled “ELECTROSTATIC CHUCK DEVICE AND COOLING PLATE” which is incorporated herein by reference in its entirety.

### BACKGROUND OF THE INVENTION

### Technical Field

The present invention relates to an electrostatic chuck device and a cooling plate.

### Description of the Related Art

Conventionally, in a semiconductor manufacturing process, an electrostatic chuck device is used to fix a wafer in a vacuum chamber. As indicated in JP 2020-113588 A, the electrostatic chuck device includes a clamping plate which clamps a target object via an electrostatic force, and a metallic cooling plate which is in contact with a back surface of the clamping plate. A coolant flows through an internal flow channel formed in the cooling plate, and cools the wafer clamped to the clamping plate. In such a way, uniformity of the surface temperature distribution of the wafer is achieved.

Here, the cooling plate is provided with an introducing port for introducing the coolant into the internal flow channel and a discharging port for discharging the coolant. The vicinity of the introducing port becomes a low-temperature region because such a region is preferentially cooled by the coolant, and since the temperature of the coolant increases as the coolant flows through the internal flow channel, the vicinity of the discharging port from which such a coolant is discharged becomes a high-temperature region. That is, a temperature gradient is generated in the cooling plate. When the temperature gradient increases, the wafer clamped to the clamping plate may be cracked by thermal stress, and also the clamping plate may be damaged.

### PRIOR ART DOCUMENT

### Patent Document

Patent Document 1: JP 2020-113588 A

### SUMMARY OF THE INVENTION

Therefore, the present invention has been made to solve the above-described problem, and an object thereof is to reduce a temperature gradient in a clamping plate to make the temperature of a target object clamped to the clamping plate uniform.

That is, an electrostatic chuck device according to the present invention is an electrostatic chuck device which clamps a target object via an electrostatic force, including: a clamping plate having a clamping surface that clamps the target object to its front surface side; and a cooling plate which is provided on a back surface side of the clamping plate and which has an internal flow channel through which a coolant flows, in which the internal flow channel forms a flow channel geometry in which flow channel elements of an identical pattern in a plan view are systematically connected.

Since the internal flow channel of the cooling plate forms the flow channel geometry in which the flow channel elements of the identical pattern in a plan view are systematically connected, it is possible for the electrostatic chuck device to have a configuration in which the coolant flows while meandering on a central portion side (radially inner side) and an outer peripheral portion side (radially outer side) of the cooling plate. As a result, a temperature difference between the central portion side and the outer peripheral portion side and a temperature difference in a circumferential direction can be reduced, and the temperature gradient in the entire clamping surface of the clamping plate can be reduced. As a result, the temperature of the target object clamped to the clamping plate can be made uniform. In addition, since the internal flow channel forms a flow channel geometry in which the flow channel elements of an identical pattern are systematically connected, the design and processing are facilitated, and the mechanical strength of the cooling plate can be increased.

As a specific embodiment, it is desirable that the internal flow channel communicate with a coolant introducing port and a coolant discharging port of the cooling plate, and repeat a change in which a distance from a central portion of the cooling plate in a radial direction increases and a change in which the distance from the central portion in the radial direction decreases from the coolant introducing port toward the coolant discharging port.

With this configuration, since the internal flow channel communicating from the coolant introducing port to the coolant discharging port repeats the increase and decrease of the distance in the radial direction in the cooling plate, the temperature difference between the central portion side and the outer peripheral portion side can be reduced, and thus the temperature gradient in the entire clamping plate can be reduced.

As a specific embodiment, it is desirable that the flow channel elements have a curved flow channel portion, a bent flow channel portion, or a folded flow channel portion therebetween.

With this configuration, since the internal flow channel communicating from the coolant introducing port to the coolant discharging port is curved, bent, or folded, the temperature difference between the central portion side and the outer peripheral portion side can be reduced, and thus the temperature gradient in the entire clamping plate can be reduced.

As a specific embodiment, it is desirable that the internal flow channel have a meandering flow channel geometry by systematically connecting the flow channel elements.

With this configuration, since the internal flow channel communicating from the coolant introducing port to the coolant discharging port meanders, the temperature difference between the central portion side and the outer peripheral portion side can be reduced, and thus the temperature gradient in the entire clamping plate can be reduced.

As a specific embodiment of the internal flow channel, it is desirable that the internal flow channel have a geometry that can be expressed by a periodic function. By using the periodic function as described above, the flow channel design for reducing the temperature gradient in the cooling plate can be simplified.

As a specific embodiment of the internal flow channel, it is desirable that the internal flow channel have a geometry that can be expressed by a Fourier series. By using the Fourier series as described above, for example, the flow channel which meanders on the radially inner side and the radially outer side of the cooling plate can be formed, and the flow channel design for reducing the temperature gradient in the cooling plate can be simplified.

As a specific embodiment of the internal flow channel, it is desirable that the internal flow channel have a fractal geometry. By using the fractal geometry as described above, for example, the flow channel which meanders on the radially inner side and the radially outer side of the cooling plate can be formed, and the flow channel design for reducing the temperature gradient in the cooling plate can be simplified.

As a specific embodiment of the internal flow channel, it is desirable that the internal flow channel have a geometry that can be expressed by a Gosper curve or a Minkowski curve. By using the Gosper curve or the Minkowski curve as described above, for example, the flow channel which meanders on the radially inner side and the radially outer side of the cooling plate can be formed, and the flow channel design for reducing the temperature gradient in the cooling plate can be simplified.

In addition, a cooling plate according to the present invention is a cooling plate used in an electrostatic chuck device which clamps a target object via an electrostatic force, including an internal flow channel through which a coolant flows, in which the internal flow channel forms a flow channel geometry in which flow channel elements of an identical pattern in a plan view are systematically connected.

As described above, according to the present invention, it is possible to reduce the temperature gradient in the clamping plate to make the temperature of the target object clamped to the clamping plate uniform.

### BRIEF DESCRIPTION OF THE DRAWINGS

FIG. 1 is a diagram schematically illustrating a configuration of an electrostatic chuck device according to an embodiment of the present invention;

FIG. 2 is a plan view illustrating a flow channel geometry (Fourier series) of a cooling plate of the embodiment;

FIG. 3 is a plan view illustrating a flow channel geometry (a Gosper curve in a fractal geometry) of the cooling plate of the embodiment; and

FIG. 4 is a simulation result indicating a temperature gradient in each flow channel geometry.

### DETAILED DESCRIPTION

Hereinafter, an embodiment of an electrostatic chuck device according to the present invention will be described with reference to the drawings.

Note that each of the drawings below is schematically illustrated with appropriate omission or exaggeration for ease of understanding. The same components are denoted by the same reference numerals, and the description thereof will be omitted as appropriate.

### <Configuration of Electrostatic Chuck Device>

An electrostatic chuck device 100 of the present embodiment is provided, for example, in a vacuum chamber of a semiconductor manufacturing device using plasma, and in the vacuum chamber, the electrostatic chuck device 100 clamps a wafer, which is a target object, via an electrostatic force.

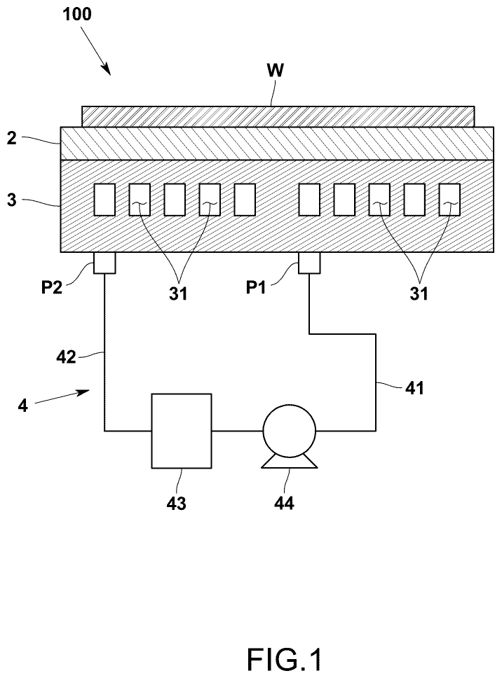

Specifically, as illustrated in FIG. 1, the electrostatic chuck device 100 includes a clamping plate 2 having a clamping surface that clamps a wafer W to its front surface side, a cooling plate 3 which is provided on a back surface side of the clamping plate 2 and which has one or a plurality of internal flow channels through which a coolant flows, and a coolant supply mechanism 4 which supplies the coolant to the cooling plate 3.

The clamping plate 2 has a circular flat plate shape made of an insulating material such as ceramics or glass, for example. An internal electrode (not illustrated) is embedded in the clamping plate 2, and a voltage is applied from an external power supply. When the voltage is applied to the internal electrode, a dielectric polarization phenomenon occurs in the clamping plate 2, and the front surface side of the clamping plate 2 becomes a clamping surface. Note that the clamping plate 2 is, for example, a bipolar type, but is not limited thereto, and may be a monopolar type.

The cooling plate 3 is a circular flat plate-shaped metal forming body having a hollow structure whose thickness is larger than that of the clamping plate 2. The cooling plate 3 of the present embodiment can be manufactured by 3D printing or additive manufacturing using metal particles containing titanium (Ti), for example.

One or a plurality of internal flow channels 31 through which the coolant flows are formed inside the cooling plate 3. The internal flow channel 31 is connected to the coolant supply mechanism 4 which is located outside the cooling plate 3, and is configured such that the coolant circulates between the cooling plate 3 and the coolant supply mechanism 4. Note that a coolant introducing port P1 and a coolant discharging port P2 connecting the internal flow channel 31 and the coolant supply mechanism 4 may each be one or more depending on the configuration of the internal flow channel 31.

The coolant supply mechanism 4 includes a coolant introducing pipe 41 connected to the coolant introducing port P1 of the cooling plate 3, a coolant discharging pipe 42 connected to the coolant discharging port P2, a cooler 43 such as a chiller unit which cools the coolant, and a circulation pump 44 which circulates the coolant. The coolant supply mechanism 4 controls the temperature of the coolant such that the coolant at, for example, −80° C. or lower is supplied to the internal flow channel 31 of the cooling plate 3.

### <Specific Configuration of Internal Flow Channel 31>

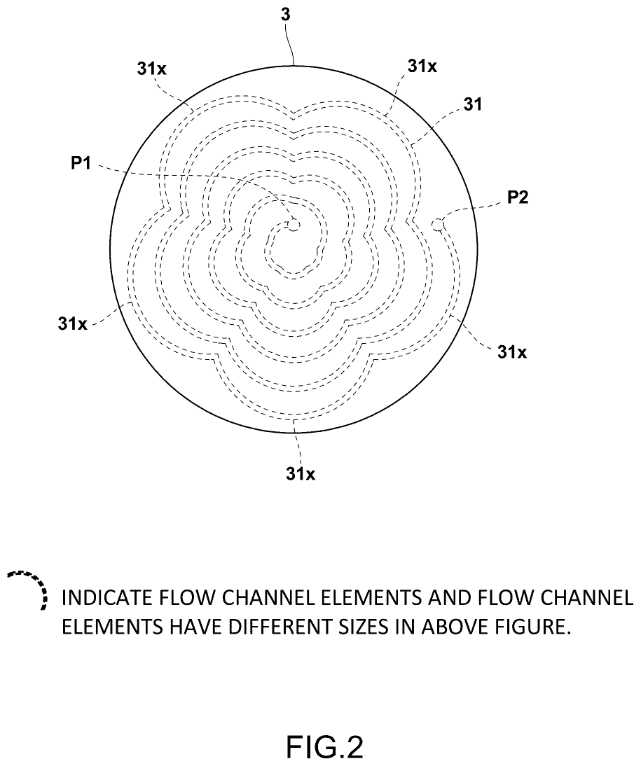

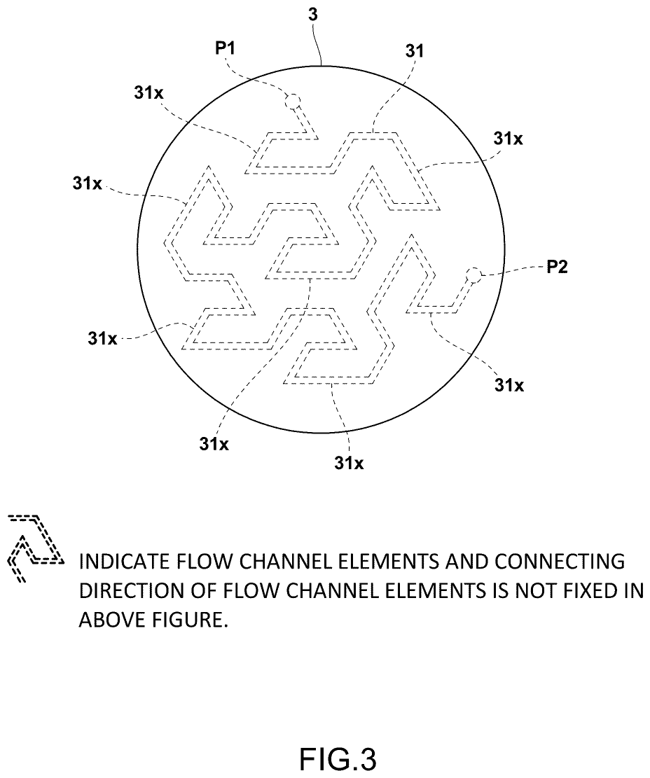

As illustrated in FIGS. 2 and 3, one or a plurality of internal flow channels 31 formed in the cooling plate 3 of the present embodiment forms a flow channel geometry in which flow channel elements 31x of an identical pattern in a plan view are systematically connected. That is, the internal flow channel 31 has a portion where the flow channel elements 31x of the identical pattern are systematically and continuously connected in the flow channel from the coolant introducing port P1 to the coolant discharging port P2.

Here, as long as the flow channel elements 31x of the identical pattern are identical or substantially identical in shape and size, arrangement positions and arrangement angles of the flow channel elements 31x may be different in the cooling plate 3. In addition, the flow channel elements 31x are curved or bent at least once in a direction (radial direction) from a central portion (radially inner side) toward an outer peripheral portion (radially outer side) of the cooling plate 3.

The internal flow channel 31 has a flow channel meandering in a direction (radial direction) from the central portion (radially inner side) toward the outer peripheral portion (radially outer side) of the cooling plate 3 in the flow channel from the coolant introducing port P1 formed in the central portion of the cooling plate 3 to the coolant discharging port P2 formed in the outer peripheral portion of the cooling plate 3 by systematically connecting the plurality of flow channel elements 31x. Furthermore, the internal flow channel 31 repeats a change in which the distance from the central portion in the radial direction increases and a change in which the distance from the central portion in the radial direction decreases from the coolant introducing port P1 toward the coolant discharging port P2. Note that the coolant introducing port P1 may be formed in the outer peripheral portion of the cooling plate 3, and the coolant discharging port P2 may be formed in the central portion of the cooling plate 3.

Here, the internal flow channel 31 may form a flow channel geometry in which the flow channel elements 31x of the identical pattern whose pattern shape is different from another identical pattern are systematically connected. For example, the internal flow channel 31 may include a first flow channel portion in which the flow channel elements 31x having a pattern shape A are systematically connected, and a second flow channel portion which is connected to a downstream side of the first flow channel portion and in which the flow channel elements 31x having a pattern shape B are systematically connected.

Specifically, each internal flow channel 31 has a geometry that can be expressed by a periodic function. More specifically, as illustrated in FIG. 2, the internal flow channel 31 has a geometry that can be expressed by a Fourier series. Furthermore, as illustrated in FIG. 3, the internal flow channel 31 may have a fractal geometry. The internal flow channel 31 in FIG. 3 indicates a geometry that can be expressed by a Gosper curve that is a fractal geometry (here, the repetition is performed twice, but the repetition may be performed three times or more). Moreover, the internal flow channel 31 may have a geometry that can be expressed by other fractal curves such as a Minkowski curve, self-avoiding walk, a Koch curve, a Takagi curve, a Dragon curve, a Hilbert curve, and a Weierstrass function.

### <Simulation Result of Temperature Gradient>

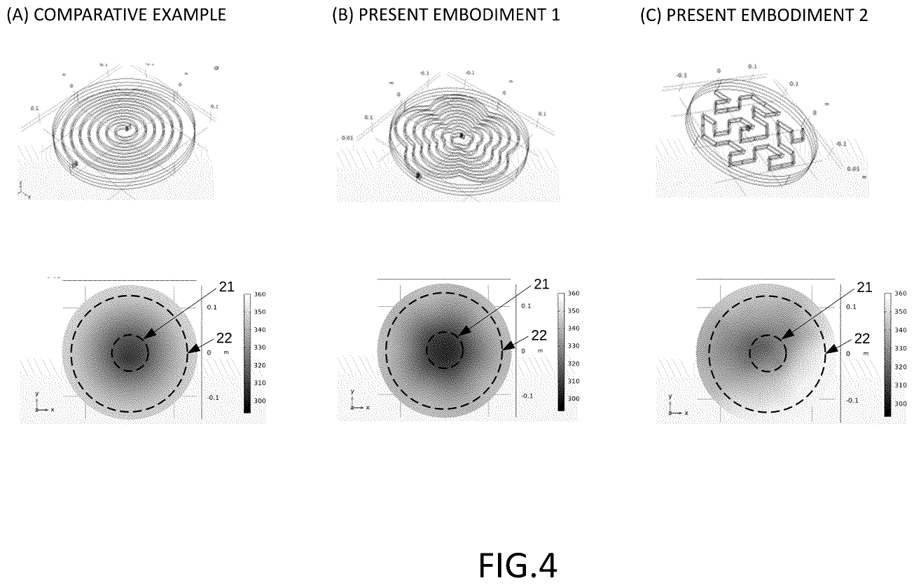

Next, a simulation result of the temperature gradient in the cooling plate having the internal flow channel of the present embodiment is indicated in FIG. 4. Here, (A) an internal flow channel formed in a spiral shape (helical shape) is indicated as a comparative example. In addition, the internal flow channel of the present embodiment has (B) a geometry that can be expressed by a Fourier series and the flow channel elements of the identical pattern connected in a spiral shape (helical shape), and has (c) a geometry that can be expressed by a quadratic Gosper curve. In these configurations, the coolant is introduced from the central portion of the cooling plate and is discharged from the outer peripheral portion of the cooling plate. In addition, flow of the coolant flowing through the internal flow channel is laminar.

As can be seen from FIG. 4, comparison between the low-temperature region surrounded by a circle 21 and the high-temperature region near a circle 22 indicates that the temperature gradient is reduced in the configuration of the present embodiment as compared with the comparative example. In the configuration of the present embodiment, since the flow channel meanders in the direction (radial direction) from the radially inner side toward the radially outer side of the cooling plate 3, it is possible to promote the heat flux in the horizontal plane (particularly, in the radial direction) of the cooling plate 3, thereby reducing the temperature gradient.

### Effects of Present Embodiment

According to the electrostatic chuck device 100 of the present embodiment as described above, since the internal flow channel of the cooling plate forms the flow channel geometry in which the flow channel elements of the identical pattern in a plan view are systematically connected, it is possible for the electrostatic chuck device 100 to have a configuration in which the coolant flows while meandering on the radially inner side and the radially outer side of the cooling plate 3. As a result, the temperature difference between the radially inner side and the radially outer side and the temperature difference in a circumferential direction can be reduced, and the temperature gradient in the entire clamping surface of the clamping plate 2 can be reduced. As a result, the temperature of the target object clamped to the clamping plate can be made uniform. In addition, since the internal flow channel forms a flow channel geometry in which the flow channel elements 31x of the identical pattern are systematically connected, the design and processing are facilitated, and the mechanical strength of the cooling plate 3 can be increased.

### Other Embodiments

For example, a metal forming a cooling plate is not limited to titanium. For example, the cooling plate may be formed by 3D printing or additive manufacturing using alloy particles containing at least nickel (Ni), molybdenum (Mo), and chromium (Cr) such as Inconel (registered trademark) or metal particles containing aluminum (Al).

Furthermore, the use of an electrostatic chuck device according to the present invention is not limited to applications such as plasma processing. The electrostatic chuck device according to the present invention may be used in a semiconductor manufacturing process performed in other chambers.

In addition, various modifications and combinations of the embodiments may be made without departing from the gist of the present invention.

### REFERENCE CHARACTERS LIST

100 electrostatic chuck device
W target object
2 clamping plate
3 cooling plate
31 internal flow channel
31x flow channel element

What is claimed is:

1. An electrostatic chuck device which clamps a target object via an electrostatic force, comprising:
a clamping plate having a clamping surface that clamps the target object to its front surface side; and
a cooling plate which is provided on a back surface side of the clamping plate and which has an internal flow channel through which a coolant flows,
wherein the internal flow channel forms a flow channel geometry in which flow channel elements of an identical pattern in a plan view are systematically connected.

2. The electrostatic chuck device according to claim 1, wherein the internal flow channel communicates with a coolant introducing port and a coolant discharging port of the cooling plate, and repeats a change in which a distance from a central portion of the cooling plate in a radial direction increases and a change in which the distance from the central portion in the radial direction decreases from the coolant introducing port toward the coolant discharging port.

3. The electrostatic chuck device according to claim 1, wherein the flow channel elements have a curved flow channel portion, a bent flow channel portion, or a folded flow channel portion therebetween.

4. The electrostatic chuck device according to claim 3, wherein the internal flow channel has a meandering flow channel geometry by systematically connecting the flow channel elements.

5. The electrostatic chuck device according to claim 1, wherein the internal flow channel has a geometry that can be expressed by a periodic function.

6. The electrostatic chuck device according to claim 1, wherein the internal flow channel has a geometry that can be expressed by a Fourier series.

7. The electrostatic chuck device according to claim 1, wherein the internal flow channel has a fractal geometry.

8. The electrostatic chuck device according to claim 1, wherein the internal flow channel has a geometry that can be expressed by a Gosper curve or a Minkowski curve.

9. A cooling plate used in an electrostatic chuck device which clamps a target object via an electrostatic force, comprising
an internal flow channel through which a coolant flows,
wherein the internal flow channel forms a flow channel geometry in which flow channel elements of an identical pattern in a plan view are systematically connected.
